(19) United States
(12) Patent Application Publication
(10) Pub. No.: US 2008/0138605 A1
(43) Pub. Date: Jun. 12, 2008

(54) COMPLEX BODY AND METHOD OF SYNTHESIS OF DIAMOND THIN LAYER

(76) Inventor: Yoshiki Takagi, Tokyo (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 11/943,634

(22) Filed: Nov. 21, 2007

(30) Foreign Application Priority Data
Nov. 22, 2006 (JP) 2006-315480

(51) Int. Cl. C23C 16/27; B32B 17/06

(52) U.S. Cl. 428/323; 428/426; 427/249.7; 428/336

(57) ABSTRACT

There are provided a process for synthesizing a diamond thin film on a glass substrate with a high coverage even when using ordinary multi-component glass having a low glass transition point (Tg) as a material of the glass substrate, and a composite article obtained by laminating the diamond thin film on the glass substrate. The present invention relates a composite article comprising a glass substrate and a diamond thin film laminated on the glass substrate, wherein the glass substrate is made of multi-component glass, and a coverage of diamond over the glass substrate is 50% or more; as well as a process for synthesizing a diamond thin film on a glass substrate made of multi-component glass in a closed chamber provided therein with a heating means, said process comprising the steps of (A) introducing hydrogen and a liquid carbon source as a carbon source for the diamond thin film into the closed chamber; and (B) heating the contents of the closed chamber by the heating means to evaporate carbon from the liquid carbon source and deposit the evaporated carbon as diamond on the glass substrate.

### BACKGROUND OF THE INVENTION

The present invention relates to a composite article obtained by laminating a diamond thin film on a glass substrate, and a process for synthesizing a diamond thin film on a glass substrate.

Diamond has been extensively used as various functional materials because of excellent abrasion resistance, high hardness, high heat conductivity, etc. For example, diamond is employed in machine tools and cutting tools by utilizing an excellent abrasion resistance and a high hardness thereof. In addition, diamond is applied to heat sink by utilizing a high heat conductivity thereof and also applied to electronic devices by utilizing good semiconductor characteristics thereof.

In particular, with the recent progress of reduction in size and high performance of electronic devices, there is a rapid demand for developing a method of removing heat generated from the electronic devices upon operation thereof in an efficient manner to avoid occurrence of defective operation of the devices owing to the heat. Under the above circumstances, it has been required to apply diamond having a very high heat conductivity to heat sink.

Upon using diamond in the above extensive applications, techniques for synthesis of diamond are inevitably needed. As the method for synthesizing diamond, there are conventionally known a synthesis method using high-temperature and high-pressure conditions, i.e., using a temperature as high as several thousand degree centigrade and a pressure as high as several thousand atm, and a method for synthesizing a diamond thin film on a silicon substrate by chemical vapor deposition (CVD), etc. However, in the former method, the synthesis conditions are very severe, whereas in the latter method, only limited substrates are usable therein.

To solve the above conventional problems, various methods have been proposed. For example, there has been proposed the method of producing a nano-diamond thin film containing a nano-crystal diamond having a crystal grain size of not less than 1 nm but less than 1000 nm as a main component on a substrate such as a glass substrate by microwave plasma CVD method (refer to Patent Document 1). In the Patent Document 1, it is described that a grain size of crystal particles forming the nano-diamond thin film can be well controlled by adjusting a temperature of the substrate, more specifically, it is described that the nano-diamond film having a thickness of 500 nm was formed on the glass substrate having a thickness of 1.1 mm using a microwave plasma CVD apparatus by adjusting a temperature of the glass substrate to 300° C. (refer to Example 2 of Patent Document 1).

However, in this Example of the Patent Document 2, it is not clear what kind of glass substrate was used therein, and there is no description concerning a coverage of the diamond thin film over the glass substrate.

Also, there has been proposed the method for synthesizing a diamond thin film on a surface of a substrate such as a glass substrate at a low temperature in which while heating and evaporating a metal porphyrin complex disposed near the surface of the substrate in an opposed relation thereto, a high-frequency discharge plasma is generated to deposit the diamond thin film on the surface of the substrate (refer to Patent Document 2). The Patent Document 2 discloses a SEM image of diamond synthesized on the glass substrate, and it is described that a crystallite having an octahedral structure which is peculiar to diamond was observed from the SEM image.

However, in the Patent Document 2, it is not clear what kind of glass substrate is used therein. Further, it is suggested from the SEM image that a coverage of the diamond thin film over the substrate is considerably low.

Meanwhile, the present inventor has proposed the technique for synthesizing a diamond thin film on a substrate made of amorphous silica glass, etc., by evaporating carbon from a solid carbon source and depositing the carbon on the substrate within a closed chamber maintained under a hydrogen atmosphere (refer to Patent Document 3). In this technique, although a coverage of the diamond thin film over the substrate is high and the resultant thin film is uniform, the temperature of the glass substrate is as high as 750° C. (refer to Example 1 of the Patent Document 3), and, therefore, the material of the substrate is limited only to those having a high glass transition point (Tg) such as silica glass.

Patent Document 1: JP 2004-176132A

Patent Document 2: JP 2006-143561A

Patent Document 3: PCT Pamphlet WO 01/81660

### SUMMARY OF THE INVENTION

In view of the above problems, an object of the present invention is to provide a process for synthesizing a diamond thin film on a substrate with a high coverage even when using ordinary multi-component glass having a low glass transition point (Tg) as a material of the substrate, and a composite article obtained by laminating the diamond thin film on the glass substrate.

The present inventor has found that a diamond thin film can be synthesized on multi-component glass with a coverage of 50% or more by the method of introducing hydrogen and a liquid carbon source as a carbon source for the diamond thin film into a closed chamber provided therein with a heating means and evaporating carbon from the liquid carbon source to deposit diamond on the glass substrate. The present invention has been accomplished on the basis of the above finding.

Thus, the present invention relates to the following aspects:

[1] A composite article comprising a glass substrate and a diamond thin film laminated on the glass substrate, wherein the glass substrate is made of multi-component glass, and a coverage of diamond over the glass substrate is 50% or more;

[2] the composite article according to the above aspect [1], wherein the multi-component glass is non-alkaline glass or soda-lime glass;

[3] the composite article according to the above aspect [1], wherein the coverage of diamond over the glass substrate is 80% or more;

[4] the composite article according to the above aspect [1], wherein the diamond thin film has a thickness of from 0.5 to 10 μm;

[5] the composite article according to the above aspect [1], wherein the diamond has an average particle size of from 10 to 5000 nm;

[6] a process for synthesizing a diamond thin film on a glass substrate made of multi-component glass in a closed chamber provided therein with a heating means, said process comprising the steps of:

(A) introducing hydrogen and a liquid carbon source as a carbon source for the diamond thin film into the closed chamber; and

(B) heating the contents of the closed chamber by the heating means to evaporate carbon from the liquid carbon source and deposit the evaporated carbon as diamond on the glass substrate;

[7] the process according to the above aspect [6], wherein the multi-component glass is non-alkaline glass or soda-lime glass;

[8] the process according to the above aspect [6], wherein the liquid carbon source is at least one compound selected from the group consisting of acetone, methanol, ethanol and ethylene glycol;

[9] the process according to the above aspect [6], wherein a temperature of the glass substrate in the step (B) is from 350 to 650° C.;

[10] the process according to the above aspect [6], wherein pressures of the hydrogen and the liquid carbon source introduced into the closed chamber in the step (A) are from 8 to 160 kPa and from 100 to 2000 Pa, respectively; and

[11] the process according to the above aspect [6], wherein the heating means comprises a heatable filament.

### EFFECT OF THE INVENTION

In accordance with the present invention, even when using ordinary multi-component glass having a low glass transition point (Tg), a diamond thin film can be synthesized on the glass with a high coverage, thereby enabling production of a composite article including a glass substrate and the diamond thin film laminated thereon.

### BRIEF DESCRIPTION OF THE DRAWINGS

FIG. 1 is a schematic view showing an inside structure of a chamber used in a synthesis process of the present invention.

FIG. 2 is a view showing a Raman spectrum of a diamond thin film synthesized in Example 1.

FIG. 3 is a SEM microphotograph of a diamond thin film synthesized in Example 1.

FIG. 4 is a view showing a Raman spectrum of a diamond thin film synthesized in Example 2.

FIG. 5 is a SEM microphotograph of a diamond thin film synthesized in Example 2.

FIG. 6 is a view showing a Raman spectrum of a diamond thin film synthesized in Example 3.

FIG. 7 is a SEM microphotograph of a diamond thin film synthesized in Example 3.

FIG. 8 is a view showing a Raman spectrum of a diamond thin film synthesized in Example 4.

FIG. 9 is a SEM microphotograph of a diamond thin film synthesized in Example 4.

EXPLANATION OF REFERENCE NUMERALS

1: Supporting member for heating means; 2: Heating means; 3: Supporting member for substrate; 4: Substrate; 5: Thermocouple

### DETAILED DESCRIPTION OF THE INVENTION

The composite article of the present invention includes a glass substrate and a diamond thin film laminated on the glass substrate. The glass substrate used in the composite article is made of multi-component glass. Specific examples of the multi-component glass include various commercial glass materials such as non-alkaline glass, soda-lime glass, borosilicate glass, alkaline barium glass and lead glass. For example, there may be used such a glass substrate having a glass transition point (Tg) of 600° C. or lower. Among these multi-component glass materials, non-alkaline glass and soda-lime glass are preferred in view of flexibility of applications thereof.

The process for producing the composite article of the present invention, i.e., the process for synthesizing the diamond thin film on the glass substrate is described in detail below.

The process of the present invention is such a process for synthesizing the diamond thin film on the glass substrate made of multi-component glass in a closed chamber provided therein with a heating means, which process includes the steps of (A) introducing hydrogen and a liquid carbon source as a carbon source for the diamond thin film into the closed chamber; and (B) heating the contents of the closed chamber by the heating means to evaporate carbon from the liquid carbon source and deposit the evaporated carbon as diamond on the glass substrate. Meanwhile, the “closed chamber” used in the present invention means a completely closed system that requires neither introduction of raw gases nor discharge or evacuation of reaction product gases.

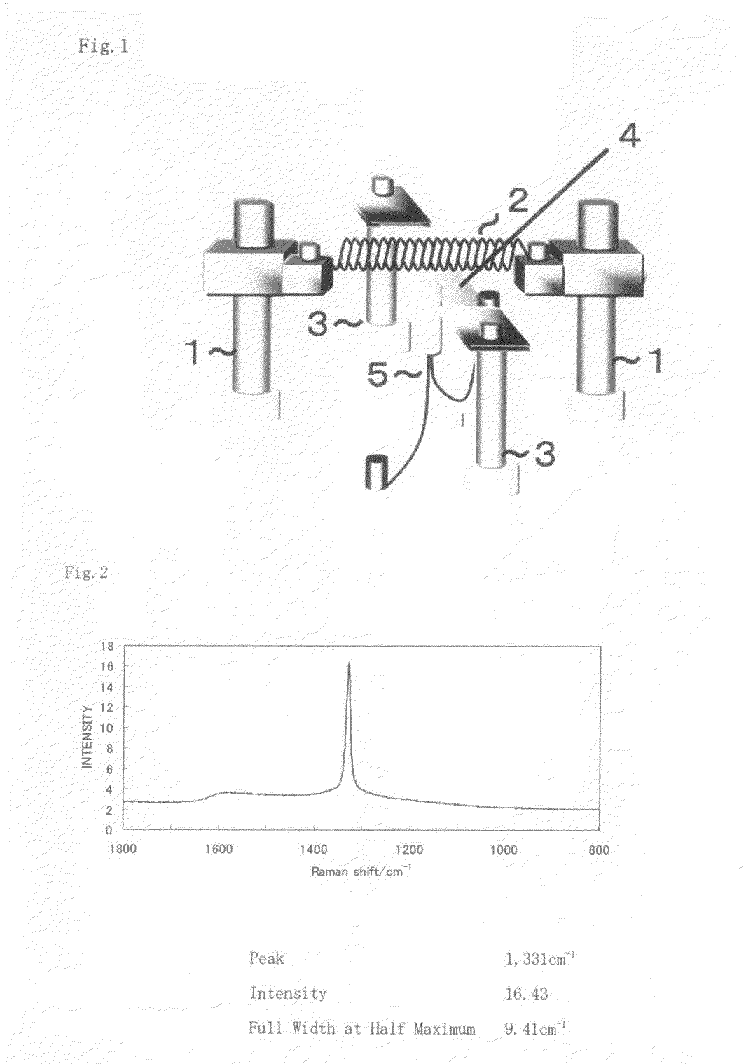

First, an apparatus used in the process for synthesizing the diamond thin film according to the present invention is explained by referring to FIG. 1. In FIG. 1, there is shown an example of an inside structure of the closed chamber provided in the apparatus for synthesizing the diamond thin film on the glass substrate. The structure is disposed within the chamber that can be hermetically closed.

In the embodiment illustrated in FIG. 1, a pair of supporting members 1 for heating means which can also serve as terminals for electric connection, are disposed uprightly, and a heating means 2 is mounted between the supporting members 1. An electric power is supplied from a power source (not shown) to the heating means 2 through the supporting members 1, thereby generating heat from the heating means 2 heated to a high temperature.

The heating means 2 is not particularly limited, and preferably constituted from a tungsten filament, etc., from the view points of stably maintaining a high temperature and effectively evaporating the liquid carbon source as described in detail herein later. In the embodiment shown in FIG. 1, the tungsten filament is used as the heating means 2. The temperature of the heating means 2 is detected, for example, by a radiation thermometer (pyrometer) disposed outside the chamber which is connected thereto through a transparent window portion of the chamber which is made of silica glass, etc.

In the embodiment shown in FIG. 1, supporting members 3 for the glass substrate are also disposed uprightly, and the glass substrate 4 is disposed between the supporting members 3 to be spaced by a predetermined distance downwardly from the heating means 2. The temperature of the glass substrate 4 is detected by a thermocouple 5. Meanwhile, the relative position between the heating means 2 and the glass substrate 4 is not particularly limited. The heating means 2 and the glass substrate 4 may be disposed such that the length axes thereof are perpendicular to each other as shown in FIG. 1, or may be disposed such that the length axes are parallel with each other. Also, the glass substrate 4 may be placed on a turn table to rotate during the synthesis of the diamond thin film.

In order to maintain an inside of the chamber under a hydrogen gas atmosphere having a predetermined pressure, the chamber is constructed such that a hydrogen gas is fed into the chamber from a hydrogen gas cylinder through a valve and a conduit. In addition, in order to discharge air from the chamber, an evacuation apparatus is connected to the chamber. Further, the chamber is equipped with a detector of a gas pressure within the chamber.

In the synthesis process of the present invention, first, the glass substrate 4 is placed in the chamber, and then the heating means 2 is disposed near above the glass substrate 4. The glass substrate 4 is made of the above-described material and preferably has cracks on its surface on which the diamond thin film is to be synthesized. The cracks formed on the surface of the glass substrate 4 serve for further facilitating synthesis of the diamond thin film thereon.

The cracks on the glass substrate may be produced, for example, by colliding a diamond powder, etc., with the surface of the glass substrate using ultrasonic vibration, etc. Also, formation of the cracks may be controlled to limited portions on the surface of the glass substrate by masking, etc., whereby the diamond thin film having an optional shape can be synthesized on optional surface portions of the glass substrate.

The distance between the heating means 2 and the glass substrate 4 is preferably kept unchanged. For example, as shown in FIG. 1, the distance between the tungsten filament (heating means 2) and the glass substrate 4 is preferably kept constant. The shape of the tungsten filament is not particularly limited, and the tungsten filament is preferably of a suspended type because the distance between the filament of such a suspended type and the glass substrate can be readily kept constant.

The temperature of the heating means 2 can be controlled by adjusting conditions such as fineness and length of the filament as well as electric current and electric voltage applied thereto, and is usually controlled to the range of from about 2000 to 2300° C. When the temperature of the heating means 2 is adjusted to the above-specified range, the temperature of the glass substrate 4 can be controlled to the range of from 350 to 600° C., thereby effectively synthesizing the diamond thin film on the glass substrate 4 without softening and melting the glass substrate 4. Meanwhile, although the glass substrate 4 is mainly heated by radiant heat generated from the heating means 2, a heater for the glass substrate 4 or a cooling means such as a water-cooling pipe may be further provided, if required.

In addition, when a back-up material such as a metal plate is disposed on a backside of the glass substrate, it is possible to heat the glass substrate to a temperature as high as about 650° C. As the back-up material, there may be used those materials having a high heat conductivity. Specific examples of the suitable back-up material include copper, etc.

Next, the chamber is closed, and air in the chamber is discharged by the evacuation apparatus preferably until the inside pressure of the chamber reaches 13 Pa (0.1 Torr) or less. Successively, hydrogen is introduced from the hydrogen gas cylinder into the chamber. Also, the liquid carbon source as a carbon source for the diamond thin film is introduced through another conduit into the chamber.

The hydrogen pressure inside of the chamber is preferably controlled to the range of from 8 to 160 kPa. When the hydrogen pressure inside of the chamber lies within the above-specified range, the diamond thin film can be efficiently synthesized on the glass substrate. From the above viewpoint, the hydrogen pressure inside of the chamber is more preferably controlled to the range of from 70 to 90 kPa.

Examples of the liquid carbon source include various compounds. In view of easiness of evaporation and handling, among them, preferred are acetone, methanol, ethanol and ethylene glycol, and more preferred are acetone and ethanol.

The pressure of the liquid carbon source in the chamber is preferably in the range of from 100 to 2000 Pa and more preferably from 270 to 800 Pa in view of synthesizing the diamond thin film in an efficient manner.

The time required for synthesizing the diamond thin film on the glass substrate is not particularly limited. As the synthesis time is prolonged, the region of formation of the diamond thin film tends to be widened, the coverage of the diamond thin film over the glass substrate tends to be increased and the thickness of the diamond thin film tends to be increased. The synthesis time is usually from about 5 to 200 min.

The composite article of the present invention which is produced by the above synthesis process, i.e., the composite article obtained by laminating the diamond thin film on the glass substrate, has a diamond coverage of 50% or more. When the conditions for synthesis of the diamond thin film is optimized, the diamond coverage of the composite article can be enhanced to 80% or more, further 90% or more and still further 99% or more.

Also, the thickness of the diamond thin film formed on the glass substrate is in the range of from 0.5 to 10 μm.

Further, the average particle size of diamond in the composite article obtained according to the present invention is in the range of from 10 to 5000 nm.

### EXAMPLES

Next, the present invention is described in more detail by referring to the following examples. However, it should be noted that the following examples are only illustrative and not intended to limit the invention thereto.

### Evaluation Methods

### (1) Raman Spectroscopic Analysis

The thin films obtained in the respective Examples were subjected to spectroscopic analysis using a Raman spectrometer “NRS-1000” available from JASCO Corporation to confirm whether or not any diamond thin film was synthesized in a wavelength range of from about 800 to 1800 cm⁻¹.

### (2) Observation Using Scanning Electron Microscope

The diamond thin films synthesized in the respective Examples were observed by a scanning electron microscope “JSM-5200” available from JEOL Ltd. Upon the measurement, the acceleration voltage applied was controlled to 25 kV for Examples 1 and 2, 15 kV for Example 3 and 5 kV for Example 4. Also, gold was vapor-deposited on the diamond thin film before the observation.

### Example 1

A substrate made of non-alkaline glass “NA35” (thickness: 1 mm) available from NH Techno-Glass Corporation was disposed within a closed chamber. A tungsten filament used as a heating means 2 was disposed in the chamber such that the distance between the heating means 2 and the glass substrate 4 was 3 mm.

A hydrogen gas and acetone as a liquid carbon source were introduced into the chamber such that the pressures of the hydrogen gas and acetone in the chamber were 79.5 kPa (596 Torr) and 533 Pa (4 Torr), respectively. The temperature of the filament was controlled to the range of from 2200 to 2300° C. such that the temperature of the glass substrate was kept constant at 550° C., and the reaction was conducted for 40 min.

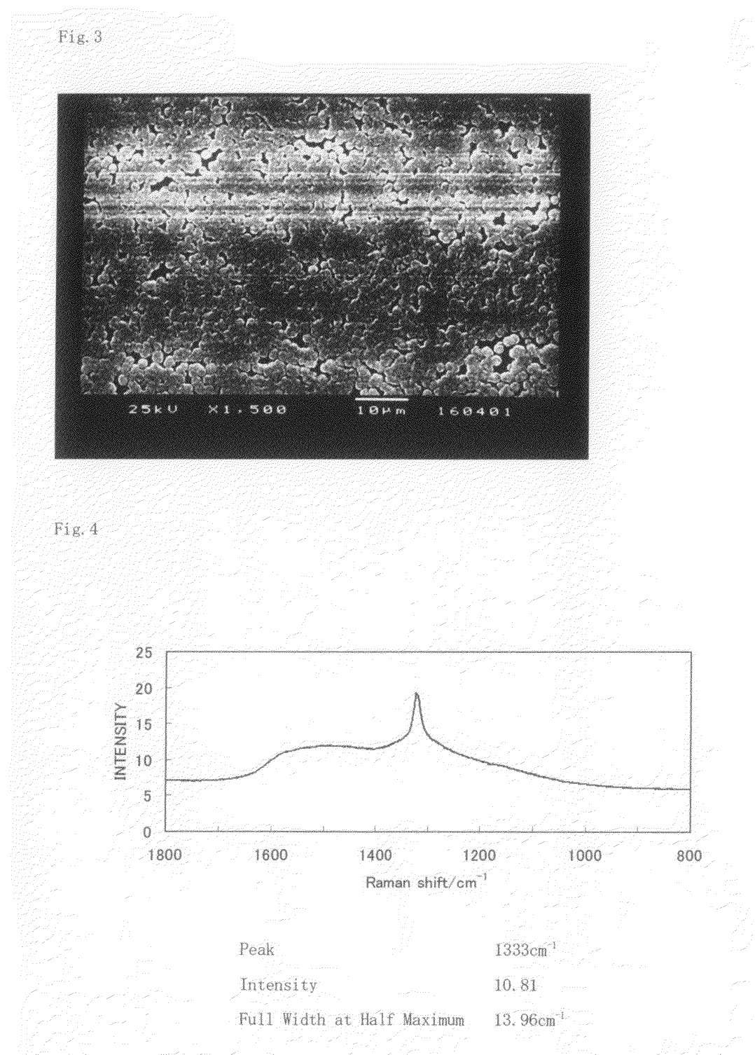

The thin film thus obtained in Example 1 was subjected to Raman spectroscopic analysis. The results are shown in FIG. 2. As shown in FIG. 2, it was confirmed that a Raman shift was observed in the Raman spectrum, and the diamond thin film was synthesized. Also, the scanning electron micrograph (SEM) of the diamond thin film obtained in Example 1 is shown in FIG. 3. As shown in FIG. 3, it was confirmed that diamond grains having an average particle size of about 2000 nm were synthesized in the form of a thin film with a coverage of about 92%.

### Example 2

A substrate made of soda-lime glass (thickness: 1 mm) available from Nippon Sheet Glass Company, Limited was disposed within a closed chamber. Similarly to Example 1, a tungsten filament used as a heating means 2 was disposed in the chamber such that the distance between the heating means 2 and the glass substrate 4 was 4 mm.

A hydrogen gas and acetone as a liquid carbon source were introduced into the chamber such that the pressures of the hydrogen gas and acetone in the chamber were 79.5 kPa (596 Torr) and 533 Pa (4 Torr), respectively. The temperature of the filament was controlled to 2000° C. such that the temperature of the glass substrate was kept constant at 440° C., and the reaction was conducted for 40 min.

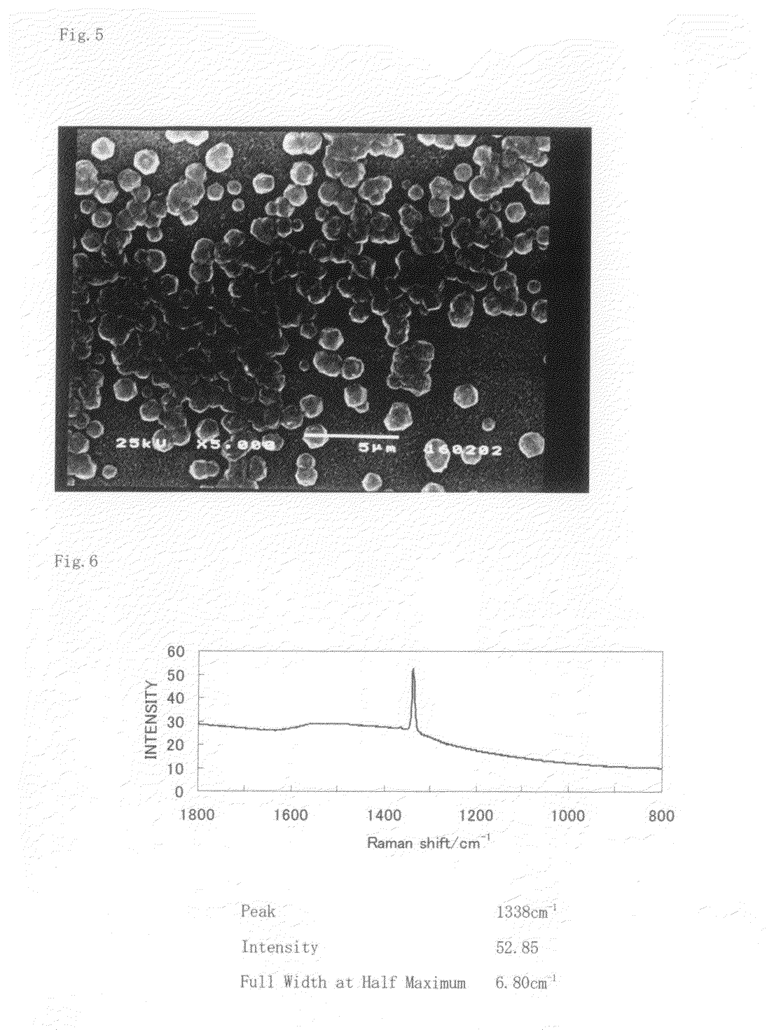

The thin film thus obtained in Example 2 was subjected to Raman spectroscopic analysis. The results are shown in FIG. 4. As shown in FIG. 4, it was confirmed that a Raman shift was observed in the Raman spectrum, and the diamond thin film was synthesized. Also, the scanning electron micrograph (SEM) of the diamond thin film obtained in Example 2 is shown in FIG. 5. As shown in FIG. 5, it was confirmed that diamond grains having an average particle size of about 1500 nm were synthesized in the form of a thin film with a coverage of about 60%.

### Example 3

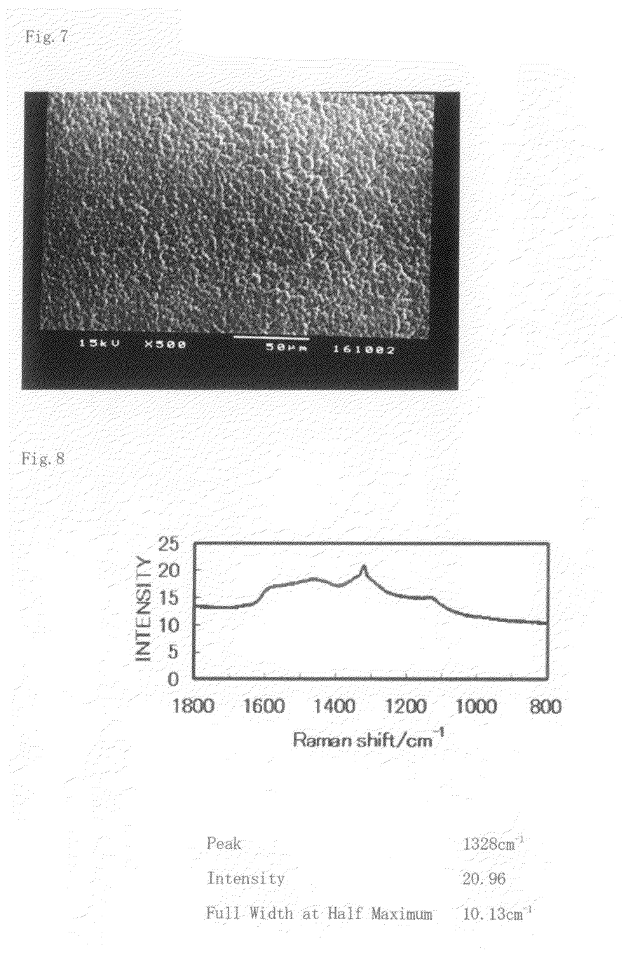

The same procedure as in Example 1 was repeated except that non-alkaline glass “NA35” (available from NH Techno-Glass Corporation) having a thickness of 0.7 mm was used as the glass substrate; a 0.7 mm-thick copper plate as a back-up material was disposed on a backside of the glass substrate; the temperature of the filament was controlled to 2600° C. such that the temperature of the glass substrate was kept constant at about 630° C.; and the reaction time was changed to 160 min, thereby synthesizing a diamond thin film. The thus obtained thin film was subjected to Raman spectroscopic analysis. The results are shown in FIG. 6. As shown in FIG. 6, it was confirmed that a Raman shift was observed in the Raman spectrum, and the diamond thin film was synthesized. Also, the scanning electron micrograph (SEM) of the obtained diamond thin film is shown in FIG. 7. As shown in FIG. 7, it was confirmed that diamond grains having an average particle size of from 3 to 4 μm were synthesized in the form of a thin film with a coverage of about 99%.

### Example 4

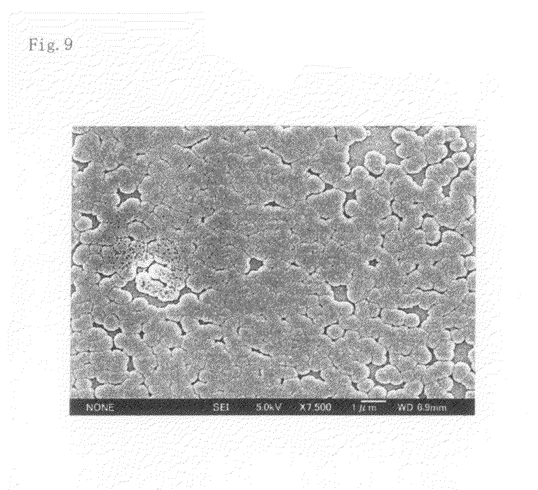

The same procedure as in Example 2 was repeated except that the temperature of the filament was controlled to 2200° C. such that the temperature of the glass substrate was kept constant at 450° C., thereby synthesizing a diamond thin film. The thus obtained thin film was subjected to Raman spectroscopic analysis. The results are shown in FIG. 8. As shown in FIG. 8, it was confirmed that a Raman shift was observed in the Raman spectrum, and the diamond thin film was synthesized. Also, the scanning electron micrograph (SEM) of the obtained diamond thin film is shown in FIG. 9. As shown in FIG. 9, it was confirmed that diamond grains having an average particle size of about 1 μm were synthesized in the form of a thin film with a coverage of about 95%.

### INDUSTRIAL APPLICABILITY

In accordance with the present invention, a diamond thin film can be synthesized even on an ordinary multi-component glass having a low glass transition point (Tg) with a high coverage. Therefore, when the surface of glass is thus coated with diamond as a protective agent, the resultant composite article is enhanced in mechanical properties, thermal properties and chemical properties, thereby allowing the article to be used in various extensive application fields.

What is claimed is:

1. A composite article comprising a glass substrate and a diamond thin film laminated on the glass substrate, wherein the glass substrate is made of multi-component glass, and a coverage of diamond over the glass substrate is 50% or more.

2. The composite article according to claim 1, wherein the multi-component glass is non-alkaline glass or soda-lime glass.

3. The composite article according to claim 1, wherein the coverage of diamond over the glass substrate is 80% or more.

4. The composite article according to claim 1, wherein the diamond thin film has a thickness of from 0.5 to 10 μm.

5. The composite article according to claim 1, wherein the diamond has an average particle size of from 10 to 5000 nm.

6. A process for synthesizing a diamond thin film on a glass substrate made of multi-component glass in a closed chamber provided therein with a heating means, said process comprising the steps of:
(A) introducing hydrogen and a liquid carbon source as a carbon source for the diamond thin film into the closed chamber; and
(B) heating the contents of the closed chamber by the heating means to evaporate carbon from the liquid carbon source and deposit the evaporated carbon as diamond on the glass substrate.

7. The process according to claim 6, wherein the multi-component glass is non-alkaline glass or soda-lime glass.

8. The process according to claim 6, wherein the liquid carbon source is at least one compound selected from the group consisting of acetone, methanol, ethanol and ethylene glycol.

9. The process according to claim 6, wherein a temperature of the glass substrate in the step (B) is from 350 to 650° C.

10. The process according to claim 6, wherein pressures of the hydrogen and the liquid carbon source introduced into the closed chamber in the step (A) are from 8 to 160 kPa and from 100 to 2000 Pa, respectively.

11. The process according to claim 6, wherein the heating means comprises a heatable filament.
